(19) United States
(12) Patent Application Publication
(10) Pub. No.: US 2004/0229465 A1
(43) Pub. Date: Nov. 18, 2004

(54) Method of manufacturing transparent substrate, transparent substrate, and organic electroluminescent device having the transparent substrate

(75) Inventors: Shogo Kiyota, Osaka (JP); Shunji Wada, Osaka (JP); Yukihiro Katoh, Osaka (JP); Naoki Kinugasa, Osaka (JP)

Correspondence Address: COHEN, PONTANI, LIEBERMAN & PAVANE, Suite 1210, 551 Fifth Avenue, New York, NY, 10176, US

(73) Assignee: Nippon Sheet Glass Co., Ltd., Osaka (JP)

(21) Appl. No.: 10/727,958

(22) Filed: Dec. 4, 2003

Related U.S. Application Data
(63) Continuation of application No. PCT/JP02/05282, filed on May 30, 2002.

(30) Foreign Application Priority Data
Jun. 4, 2001 (JP) 2001-168667

(51) Int. Cl. H01L 21/302; H01L 21/461

(52) U.S. Cl. 438/689

(57) ABSTRACT

An organic EL device 10 is comprised of an ITO film-formed substrate 4 that is comprised of a glass substrate 1, an SiO₂ film 2 that is formed on a surface of the glass substrate 1 and is for alkaline passivation, and an ITO film 3 that is formed on the surface of the SiO₂ film 2, a hole transport layer 5 that is formed on the surface of the ITO film 3 and is for efficiently injecting holes into a light-emitting layer 6, a thin metallic film layer 7 that is formed on the light-emitting layer 6 and is for injecting electrons into the light-emitting layer 6, and the light-emitting layer 6 which emits light upon recombination of the injected holes and electrons. The surface smoothness of the glass substrate 1 is controlled to satisfy 0 nm≦Rz≦4 nm. As a result, non-luminescent spots do not occur and hence durability can be improved.

This application is a U.S. Continuation Application under 35 USC 371 of International Application PCT/JP02/05282 filed 30 May 2002.

### TECHNICAL FIELD

The present invention relates to a method of manufacturing a transparent substrate, such a transparent substrate, and an organic electroluminescent (hereinafter referred to as “EL”) device having the transparent substrate, and in particular relates to a method of manufacturing a transparent substrate that is to have a transparent conductive film formed on a surface thereof, such a transparent substrate, and an organic EL device having the transparent substrate.

### BACKGROUND ART

Organic EL devices, which generally have a transparent substrate such as a glass substrate having a transparent conductive film used as an anode formed on a surface thereof, are attracting attention as devices that can be used in flat surface light sources, next-generation flat panel displays, and so on. A material having a high transmissivity to light and low resistance is used for the transparent conductive film; for example, indium tin oxide (hereinafter referred to as “ITO”), which is comprised of indium oxide (In₂O₃) having tin (Sn) added thereto, is known as such as material. In such an organic EL device, holes injected in from the anode reach a light-emitting layer via a hole transport layer, and electrons injected in from a cathode reach the light-emitting layer via an electron transport layer, and these holes and electrons recombine in the light-emitting layer, whereby emission of light is realized.

However, with the conventional organic EL device, if height differences on the surface of the anode (i.e. surface undulations) are large, then an electric field may be concentrated at the projecting parts and hence the EL device may fail, or the projecting parts may short with the cathode, resulting in non-luminescent spots (spots on the surface of the EL device where light is not emitted). If such phenomena occur, then the durability of the organic EL device will drop markedly, and hence the transparent substrate on which the transparent conductive film (ITO film) that acts as the anode is formed is required to have excellent smoothness.

A glass substrate used as the transparent substrate generally has the surface thereof polished with a polishing pad or the like using a polishing agent to remove waviness and so on arising during the manufacture; during the polishing, the surface of the glass substrate may be scratched by the polishing agent or foreign matter such as polishing waste, and/or polishing agent may remain on the surface of the glass substrate. If an ITO film is formed on such a glass substrate that has been scratched and/or has polishing agent remaining thereon, then the scratches and/or polishing agent will affect the smoothness of the ITO film, and hence local projecting parts will be produced; it thus becomes necessary to polish the surface of the ITO film.

However, if the surface of the ITO film is polished with a polishing pad or the like using a polishing agent, then the surface of the ITO film will be scratched by the polishing agent or foreign matter that has got in between the glass substrate and the polishing pad, and as a result there has been a problem of non-luminescent spots or the like arising during the manufacture of organic EL devices, and hence the yield of organic EL devices dropping. Moreover, the necessity of having a polishing step of polishing the surface of the ITO film has also resulted in an increase in costs.

It is an object of the present invention to provide a method of manufacturing a transparent substrate according to which non-luminescent spots do not occur and hence durability can be improved, such a transparent substrate, and an organic EL device having the transparent substrate.

### DISCLOSURE OF THE INVENTION

To attain the above object, according to a first aspect of the present invention, there is provided a method of manufacturing a transparent substrate that is to have a transparent conductive film formed on a surface thereof, comprising controlling a surface smoothness of the surface of the transparent substrate to satisfy 0 nm≦Rz<4 nm.

In the first aspect, it is preferable to carry out the controlling of the surface smoothness by omitting polishing of the surface of the transparent substrate.

In the first aspect, more preferably, the surface of the transparent substrate is subjected to etching using an acidic aqueous solution containing hydrofluoric acid or an alkaline aqueous solution containing potassium hydroxide or sodium hydroxide.

In the first aspect, yet more preferably, after the etching has been carried out, the surface of the transparent substrate is subjected to alkaline washing comprising washing using an alkaline liquid.

In the first aspect, it is also preferable to carry out the controlling of the surface smoothness mainly by polishing the surface of the transparent substrate.

In the first aspect, more preferably, the polishing of the surface of the transparent substrate is carried out using a cerium oxide powder having a predetermined mean particle diameter, and after the polishing of the surface of the transparent substrate has been carried out, the surface of the transparent substrate is washed using a mixed liquid of sulfuric acid and ascorbic acid or a mixed liquid of nitric acid and ascorbic acid, and after the surface of the transparent substrate has been washed, the surface of the transparent substrate is subjected to etching using an acidic aqueous solution containing hydrofluoric acid or an alkaline aqueous solution containing potassium hydroxide or sodium hydroxide.

In the first aspect, also more preferably, polishing of the surface of the transparent substrate is carried out using a cerium oxide powder having a predetermined mean particle diameter, and is then further carried out using a cerium oxide powder having a mean particle diameter lower than the predetermined mean particle diameter.

In the first aspect, yet more preferably, after the polishing of the surface of the transparent substrate has been carried out, the surface of the transparent substrate is washed using a mixed liquid of sulfuric acid and ascorbic acid or a mixed liquid of nitric acid and ascorbic acid.

In the first aspect, yet more preferably, after the surface of the transparent substrate has been washed, the surface of the transparent substrate is subjected to alkaline washing comprising washing using an alkaline liquid.

In the first aspect, also yet more preferably, after the surface of the transparent substrate has been washed, the surface of the transparent substrate is subjected to etching using an acidic aqueous solution containing hydrofluoric acid or an alkaline aqueous solution containing potassium hydroxide or sodium hydroxide.

In the first aspect, also yet more preferably, after the polishing of the surface of the transparent substrate has been carried out, the surface of the transparent substrate is subjected to etching using an acidic aqueous solution containing hydrofluoric acid or an alkaline aqueous solution containing potassium hydroxide or sodium hydroxide.

To attain the above object, according to a second aspect of the present invention, there is provided a transparent substrate manufactured using a method of manufacturing a transparent substrate according to the first aspect of the present invention.

In the second aspect, preferably, a transparent conductive film is formed on the surface of the transparent substrate, and a surface smoothness of a surface of the transparent conductive film satisfies 0 nm≦Rz≦8 nm.

To attain the above object, according to a third aspect of the present invention, there is provided a transparent substrate that is to have a transparent conductive film formed on a surface thereof, wherein a surface smoothness of the surface of the transparent substrate satisfies 0 nm≦Rz≦4 nm.

In the third aspect, it is preferable for polishing of the surface to have been omitted.

In the third aspect, more preferably, the surface has been subjected to etching using an acidic aqueous solution containing hydrofluoric acid or an alkaline aqueous solution containing potassium hydroxide or sodium hydroxide.

In the third aspect, yet more preferably, after the etching has been carried out, the surface has been subjected to alkaline washing comprising washing using an alkaline liquid.

In the third aspect, it is also preferable for the surface to have been polished.

In the third aspect, more preferably, the polishing of the surface has been carried out using a cerium oxide powder having a predetermined mean particle diameter, and after the polishing of the surface has been carried out, the surface has been washed using a mixed liquid of sulfuric acid and ascorbic acid or a mixed liquid of nitric acid and ascorbic acid, and after the surface has been washed, the surface has been subjected to etching using an acidic aqueous solution containing hydrofluoric acid or an alkaline aqueous solution containing potassium hydroxide or sodium hydroxide.

In the third aspect, also more preferably, polishing of the surface has been carried out using a cerium oxide powder having a predetermined mean particle diameter, and has then further been carried out using a cerium oxide powder having a mean particle diameter lower than the predetermined mean particle diameter.

In the third aspect, yet more preferably, after the polishing of the surface has been carried out, the surface has been washed using a mixed liquid of sulfuric acid and ascorbic acid or nitric acid and ascorbic acid.

In the third aspect, yet more preferably, after the surface has been washed, the surface has been subjected to alkaline washing comprising washing using an alkaline liquid.

In the third aspect, also yet more preferably, after the surface has been washed, the surface has been subjected to etching using an acidic aqueous solution containing hydrofluoric acid or an alkaline aqueous solution containing potassium hydroxide or sodium hydroxide.

In the third aspect, also yet more preferably, after the polishing of the surface has been carried out, the surface has been subjected to etching using an acidic aqueous solution containing hydrofluoric acid or an alkaline aqueous solution containing potassium hydroxide or sodium hydroxide.

In the third aspect, yet more preferably, a transparent conductive film is formed on the surface of the transparent substrate, and a surface smoothness of a surface of the transparent conductive film satisfies 0 nm≦Rz≦8 nm.

To attain the above object, according to a fourth aspect of the present invention, there is provided an electroluminescent device having a transparent substrate according to the second or third aspect of the present invention.

### BRIEF DESCRIPTION OF THE DRAWINGS

FIG. 1 is a schematic sectional view showing the construction of an organic EL device according to an embodiment of the present invention; and

FIG. 2 is a view of the internal structure of an ion plating apparatus used in the manufacture of an ITO film-formed substrate 4 appearing in FIG. 1.

### BEST MODE FOR CARRYING OUT THE INVENTION

The present inventors carried out assiduous studies to attain the above object, and as a result discovered that, in a method of manufacturing a transparent substrate that is to have a transparent conductive film formed on a surface thereof, if the surface smoothness of the surface of the transparent substrate is controlled to satisfy 0 nm≦Rz≦4 nm, then non-luminescent spots do not occur and hence durability can be improved.

Moreover, the present inventors discovered that it is preferable to control the surface smoothness by omitting polishing of the surface of the transparent substrate, whereby polishing of the surface of the transparent substrate becomes unnecessary, and hence costs can be reduced, and moreover the transparent substrate production efficiency can be improved; moreover, the present inventors discovered that it is also preferable to control the surface smoothness mainly by polishing the surface of the transparent substrate, whereby the surface smoothness of the surface of the transparent substrate can be controlled reliably.

Furthermore, the present inventors discovered that in the case of a transparent substrate that has had the surface smoothness of a surface thereof controlled to satisfy 0 nm≦Rz≦4 nm, and has had a transparent conductive film formed on the surface thereof, if the surface smoothness of the surface of the transparent conductive film satisfies 0 nm≦Rz≦8 nm, then the transparent substrate can be used in an organic EL device having more improved durability with no non-luminescent spots.

The present invention was accomplished based on the above findings.

A method of manufacturing a transparent substrate according to an embodiment of the present invention will now be described with reference to the drawings.

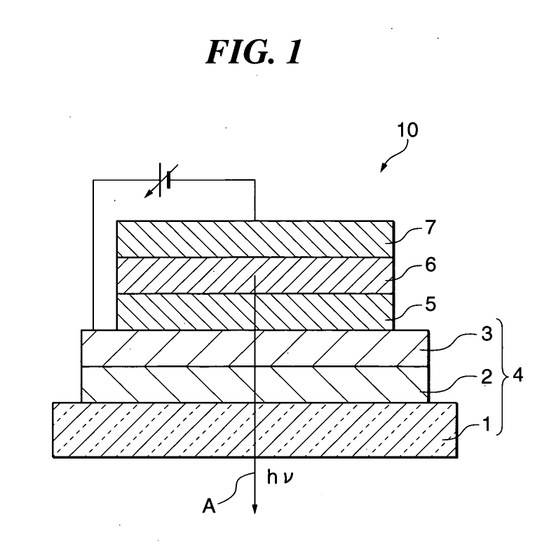

FIG. 1 is a schematic sectional view showing the construction of an organic EL device according to an embodiment of the present invention.

In FIG. 1, the organic EL device 10 is comprised of an ITO film-formed substrate 4 (a transparent substrate having a transparent conductive film formed thereon) that is comprised of a glass substrate 1 (transparent substrate) made of soda lime or the like, an SiO₂ film (silicon oxide film) 2 that is formed on a surface of the glass substrate 1 and is for alkaline passivation, and an ITO film 3 (transparent conductive film) that is formed on the surface of the SiO₂ film 2, a hole transport layer 5 that is formed on the surface of the ITO film 3 and is for efficiently injecting holes into a light-emitting layer 6, a thin metallic film layer 7 that is formed on the light-emitting layer 6 and is for injecting electrons into the light-emitting layer 6, and the light-emitting layer 6 which emits light using recombination of the injected holes and electrons; a direct current voltage is applied between the ITO film 3 and the thin metallic film layer 7 using a variable direct current power source.

The hole transport layer 5 and the light-emitting layer 6 are both made of an organic material. As the organic material constituting the hole transport layer 5, for example TPD (triphenyl diamine) or m-MTDATA (4,4′,4′-tris(N-(3-methylphenyl)-N-phenylamino)triphenylamine) is used. Moreover, the light-emitting layer 6 is made of a parent material containing a dopant, and as the organic material constituting the parent material, for example an aluminum quinolinol complex (Alq3) or DPVBi (4,4′-bis(2,2′-diphenylvinyl)-biphenyl) can be used. As the metallic material constituting the thin metallic film layer 7, a metallic material such as Al, Mg, In, Ag, In—Li, Mg—Sr or Al—Sr can be used.

With the organic EL device 10 constructed as described above, taking the ITO film 3 as an anode and the thin metallic film layer 7 as a cathode, if a direct current voltage is applied between the ITO film 3 and the thin metallic film layer 7, then holes from the ITO film 3 reach the light-emitting layer 6 via the hole transport layer 5, and electrons from the thin metallic film layer 7 reach the light-emitting layer 6, and these holes and electrons recombine in the light-emitting layer 6, whereby light is emitted, mostly in the direction of the arrow A in FIG. 1.

However, if there are marked surface undulations on the ITO film-formed substrate 4 that acts as the anode, i.e. surface height differences are large, then an electric field may be concentrated at the projecting parts, and hence small electrical discharges may occur, and thus the organic EL device 10 may fail, or non-luminescent spots may arise, i.e. the durability of the organic EL device 10 will be markedly reduced. Consequently, to maintain a good light emission state and improve durability, the surface of the ITO film-formed substrate 4 is required to have as small as possible surface height differences, i.e. an excellent value of Rz (10-point mean roughness), which represents the surface smoothness. The 10-point mean roughness Rz, which represents the surface smoothness, is the difference between the mean value of the heights of the highest to fifth highest peaks over a sampled portion relative to a reference height, and the mean value of the heights of the deepest to fifth deepest troughs over the sampled portion relative to the reference height.

In a first embodiment of the present invention, first, a glass substrate 1 already having a surface smoothness satisfying 0 nm≦Rz≦4 nm is used. This is because the surface smoothness Rz of the ITO film-formed substrate 4 is greatly influenced by the surface,smoothness Rz of the glass substrate 1. By using such a glass substrate 1, the surface smoothness Rz of the ITO film-formed substrate 4 can be improved.

Polishing of the surface of the glass substrate 1 satisfying 0 nm≦Rz≦4 nm is then omitted. This is because local projections or the like would arise on the surface of the glass substrate 1 due to polishing agent (e.g. cerium oxide powder) and/or polishing waste remaining after the polishing, and scratches and the like arising on the surface through the polishing. By omitting polishing, a worsening of the surface smoothness Rz of the glass substrate 1, and hence of the ITO film-formed substrate 4, can be prevented.

Next, if required, it is preferable to subject the surface to etching using a hydrofluoric acid aqueous solution (acidic aqueous solution) as an etchant to control the surface smoothness Rz of the glass substrate 1, thus further improving the surface smoothness Rz of the glass substrate 1. In the case that such etching has been carried out, it is further preferable to subject the surface to washing using a predetermined alkaline liquid (hereinafter referred to as “alkaline washing”), whereby the surface of the glass substrate 1, which has become rough due to the etchant, can be restored, and hence the transparency can be increased.

As a result of the above, the surface smoothness of the glass substrate 1 to be used in the first embodiment can be made to satisfy 0 nm≦Rz≦4 nm.

Moreover, in a second embodiment, the surface of a glass substrate 1 is subjected mainly to polishing to improve the surface smoothness of the glass substrate 1 to 0 nm≦Rz≦4 nm, and then this glass substrate 1 is used. This is because the surface smoothness Rz of the ITO film-formed substrate 4 is greatly influenced by the surface smoothness Rz of the glass substrate 1. By using such a glass substrate 1, the surface smoothness Rz of the ITO film-formed substrate 4 can be improved.

In the case that such polishing has been carried out, it is preferable to subject the surface to washing using a mixed liquid of sulfuric acid and ascorbic acid (hereinafter referred to as “mixed liquid washing”) or carry out etching as described above, and it is more preferable to carry out such mixed liquid washing followed by such etching. Through the mixed liquid washing, polishing agent on the surface of the glass substrate 1 remaining after the polishing can be removed effectively. Moreover, after the mixed liquid washing has been carried out, it is further preferable to carry out alkaline washing, whereby the surface of the glass substrate 1, which has become rough due to the mixed liquid, can be restored, and hence the transparency can be increased.

In the case of carrying out polishing as described above, for example a cerium oxide powder having a mean particle diameter of approximately 1 μm is used as the polishing agent (stage 1 polishing). However, if only stage 1 polishing is carried out, then it will be essential to subject the surface of the polished glass substrate 1 to mixed liquid washing and then etching. Consequently, finishing polishing may be carried out after the stage 1 polishing, in which case for example a cerium oxide powder having a smaller mean particle diameter of approximately 0.6 μm can be used as the polishing agent (stage 2 polishing). By carrying out such finishing polishing, the surface smoothness of the glass substrate 1 can be controlled to satisfy 0 nm≦Rz≦4 nm more reliably.

As a result of the above, the surface smoothness of the glass substrate 1 to be used in the second embodiment can be made to satisfy 0 nm≦Rz≦4 nm.

If an ITO film-formed substrate 4 is prepared using a glass substrate 1 for which the surface smoothness has been controlled to satisfy 0 nm≦Rz≦4 nm as described above, then local projecting parts and so on are not seen on the surface of the ITO film-formed substrate 4 whatsoever, and an ITO film-formed substrate 4 having an extremely smooth ITO film with a surface smoothness satisfying 0 nm≦Rz≦8 nm can be obtained.

The parent material glass of the glass substrate 1 may have been manufactured by any manufacturing method, so long as it is sheet glass; for example, sheet glass manufactured by a float process in which sheet glass is formed to a predetermined thickness on a molten metal is preferable.

In the float process, raw materials are mixed together to form a predetermined composition, the raw materials are put into a melting furnace, and melting and homogenization are carried out at a high temperature over a long time period in the melting furnace. Next, the molten glass is poured onto molten metal (e.g. tin (Sn)) in a forming bath that has a hermetically sealed structure containing a reducing atmosphere, whereby a glass sheet is formed to a predetermined thickness. After that, cooling is carried out down to room temperature in an annealing furnace while preventing warping. With this sheet glass production method, the sheet glass is formed to a predetermined thickness on molten metal, and hence high-quality glass that is excellent in terms of uniformity of thickness and smoothness can be produced, and moreover the glass can be produced in large amounts continuously, and hence productivity is extremely high.

Next, a description will be given of a method of manufacturing the ITO film-formed substrate 4 appearing in FIG. 1.

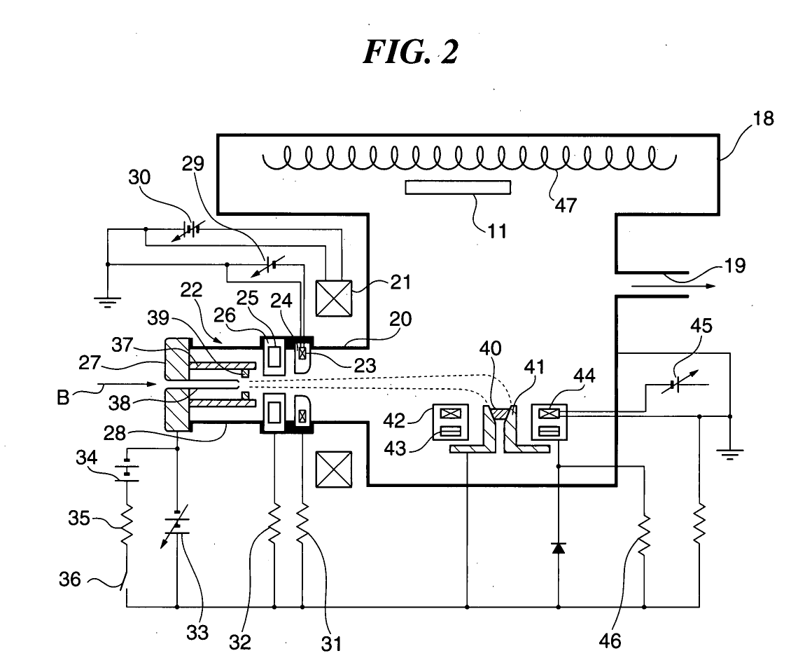

FIG. 2 is a view of the internal structure of an ion plating apparatus used in the manufacture of the ITO film-formed substrate 4 appearing in FIG. 1.

In FIG. 2, reference numeral 11 represents a glass substrate made of soda lime or the like. A vacuum vessel 18, which acts as a film deposition chamber, has an exhaust port 19 provided in a side wall on one side thereof, and has a tubular part 20 provided in a side wall on the other side thereof. A pressure gradient type plasma gun 22 is installed in the tubular part 20, and moreover a converging coil 21 is provided surrounding the tubular part 20.

The plasma gun 22 is comprised of a second intermediate electrode 24 that has an electromagnetic coil 23 built therein and is connected to the tubular part 20, a first intermediate electrode 26 that has a ring permanent magnet 25 built therein and is provided parallel to the second intermediate electrode 24, a cathode 27, and a cylindrical glass tube 28 that is interposed between the cathode 27 and the first intermediate electrode 26.

The electromagnetic coil 23 is excited by a power source 29, and the converging coil 21 is excited by a power source 30. The power source 29 and the power source 30 are both made to be variable power sources.

The second intermediate electrode 24 and the first intermediate electrode 26 are connected to one end (the positive side) of a variable voltage type main power source 33 via suspended resistors 31 and 32 respectively, and the cathode 27 is connected to the other end (the negative side) of the main power source 33. Moreover, an auxiliary discharge power source 34 and a suspended resistor 35 are connected in parallel with the main power source 33 via a switch 36.

Moreover, a cylindrical member 37 that is made of Mo (molybdenum) and is fixed to the cathode 27, a pipe 38 that is made of Ta (tantalum), and a disk-shaped member 39 that is made of LaB₅ and is fixed to the cylindrical member 37 in front of the pipe 38, are provided inside the glass tube 28, and a discharge gas (e.g. Ar gas containing a predetermined amount of oxygen) is fed into the plasma gun 22 via the pipe 38 in the direction of the arrow B.

A main hearth 41 housing an ITO sintered body 40 as a tablet (a substance to be evaporated) is provided in a bottom portion of the vacuum vessel 18, and moreover an auxiliary hearth 42 is provided surrounding the main hearth 41. The main hearth 41 is made of an electrically conductive material having good thermal conductivity, for example copper, and has formed therein a recess into which a plasma beam from the plasma gun 22 is fired, and moreover is connected to the positive side of the main power source 33 to form an anode, thus attracting the plasma beam.

As with the main hearth 41, the auxiliary hearth 42 is also made of an electrically conductive material such as copper having good thermal conductivity; a ring permanent magnet 43 and an electromagnet 44 are housed in the auxiliary hearth 42, and the electromagnet 44 is excited by a hearth coil power source 45, which is a variable power source. The construction of the auxiliary hearth 42 is thus such that the ring permanent magnet 43 and the electromagnet 44 are provided on top of one another coaxially within the same annular vessel which surrounds the main hearth 41, and moreover the electromagnet 44 is connected to the hearth coil power source 45, and hence the magnetic field formed by the ring permanent magnet 43 and the magnetic field formed by the electromagnet 44 are superimposed on one another. In this case, the direction of the magnetic field on the inside generated by the ring permanent magnet 43 and the direction of the magnetic field on the inside from the electromagnet 44 are the same, and by varying the voltage of the hearth coil power source 45, the current supplied to the electromagnet 44 can be varied.

Moreover, as with the main hearth 41, the auxiliary hearth 42 is also connected to the positive side of the main power source 33 via a suspended resistor 46 to form an anode.

Furthermore, a heater 47 is provided in an upper portion of the vacuum vessel 18, and the glass substrate 11 is heated to a predetermined temperature using the heater 47.

With the ion plating apparatus constructed as described above, if an ITO sintered body 40 having a tin oxide (SnO₂) content of 4 to 6 mass % is housed in the recess of the main hearth 41, and a discharge gas is fed through the pipe 38 from the cathode 27 side of the plasma gun 22, then a discharge is generated between the plasma gun 22 and the main hearth 41, whereby a plasma beam is produced. The plasma beam is converged by the ring permanent magnet 25 and the electromagnetic coil 23, and is then guided by a magnetic field determined by the converging coil 21 and by the ring permanent magnet 43 and the electromagnet 44 inside the auxiliary hearth 42, and thus reaches the main hearth 41.

The ITO sintered body 40 housed in the main hearth 41 is heated by the plasma beam and thus evaporates, the evaporated particles are ionized by the plasma beam, whereby an ITO film is formed on the glass substrate 11 that is being heated by the heater 47.

According to the embodiment described above, the organic EL device 10 is comprised of an ITO film-formed substrate 4 that is comprised of a glass substrate 1, an SiO₂ film 2 that is formed on a surface of the glass substrate 1 and is for alkaline passivation, and an ITO film 3 that is formed on the surface of the SiO₂ film 2, a hole transport layer 5 that is formed on the surface of the ITO film 3 and is for efficiently injecting holes into a light-emitting layer 6, a thin metallic film layer 7 that is formed on the light-emitting layer 6 and is for injecting electrons into the light-emitting layer 6, and the light-emitting layer 6 which emits light using recombination of the injected holes and electrons; the surface smoothness of the glass substrate 1 satisfies 0 nm≦Rz≦4 nm, and hence non-luminescent spots do not occur and thus durability can be improved, and moreover costs can be reduced. Furthermore, the organic EL device 10 has a glass substrate 1 having a surface smoothness satisfying 0 nm≦Rz≦4 nm, and thus an ITO film-formed substrate 4 having a surface smoothness satisfying 0 nm≦Rz≦8 nm, and hence a drop in manufacturing yield can be prevented, and durability can be improved, and moreover costs can be reduced.

In the embodiment described above, the mixed liquid washing and the etching were made to be separate steps, but these may also be carried out in the same step by using an aqueous solution containing both the mixed liquid used in the mixed liquid washing and the etchant used in the etching. As a result, the removal of the polishing agent and the etching can be carried out simultaneously.

Moreover, in the embodiment described above, the mixed liquid used in the mixed liquid washing was made to be a mixed liquid of sulfuric acid and ascorbic acid, but the mixed liquid may also be made to be a mixed liquid of nitric acid and ascorbic acid. Moreover, the etchant was made to be an acidic aqueous solution containing a strong acid such as hydrofluoric acid, but the etchant may also be made to be an alkaline aqueous solution containing a strong alkali such as potassium hydroxide or sodium hydroxide.

### EXAMPLES

A description will now be given of first examples of the present invention.

The present inventors prepared ITO film-formed substrates 4 using glass substrates 1 having different surface smoothnesses Rz and manufacturing conditions, and moreover prepared organic EL devices 10 from the ITO film-formed substrates 4 (Examples 1 to 7, Comparative Examples 1 to 4).

Specifically, glass substrates 1 having different surface smoothnesses Rz and manufacturing conditions were each washed with a dipping-type ultrasonic washing machine using an alkaline detergent, and then dried in a warm air current. Next, each glass substrate 1 was put into an in-line-type vacuum deposition apparatus, heating to approximately 220° C. and exhaustion were carried out, and then Ar gas was introduced, the pressure was adjusted to 0.4 to 0.7 Pa, and an SiO₂ film 2 for alkaline passivation was formed using radio-frequency magnetron sputtering. Without exposing the glass substrate 1 having the SiO₂ film 2 formed thereon to the atmosphere, an ITO film 3 was then formed using an ion plating apparatus as shown in FIG. 2. As a result, an ITO film-formed substrate 4 was prepared from each glass substrate 1.

Next, each ITO film-formed substrate 4 was put into a vacuum deposition apparatus, evacuation was carried out down to a pressure of not more than 1.3×10⁻⁴ Pa, and then triphenyl diamine (TPD) as a hole transport layer 5 and an aluminum quinolinol complex (Alq3) as a light-emitting layer 6 were formed. Next, an MgAg alloy film (Mg:Ag=10:1), which is a thin metallic film layer 7, was formed on the organic layers as a cathode. Without exposing the ITO film-formed substrate 4 on which the above films had been formed to the atmosphere, nitrogen gas was introduced into a vacuum chamber, and the ITO film-formed substrate 4 was fixed to a glass substrate and sealing between them were carried out using an epoxy resin. As a result, an organic EL device 10 was prepared from each ITO film-formed substrate 4.

The surface smoothnesses Rz of the glass substrates 1 having different surface smoothnesses Rz and manufacturing conditions, and of the ITO films 3 of the prepared ITO film-formed substrates 4 were measured using an atomic force microscope, and moreover a direct current was applied to each of the prepared organic El devices 10, and the light emission characteristics thereof were evaluated. The results are shown in Table 1.

TABLE 1

| | Glass Substrate Manufacturing Conditions | | | | Rz of | Rz of | Non- |
|---|---|---|---|---|---|---|---|
| | Stage 1 | Mixed Liquid | | Alkaline | Glass | ITO | Luminescent |
| | Polishing | Washing | Etching | Washing | Substrate | Film | Spots Present? |
| Examples | | | | | | | |
| 1 | — | — | — | — | 4 nm | 7 nm | No |
| 2 | — | — | ◯ | — | 3 nm | 6 nm | No |
| 3 | — | — | ◯ | ◯ | 2 nm | 4 nm | No |
| 4 | ◯ | ◯ | ◯ | — | 4 nm | 8 nm | No |
| 5 | ◯ | ◯ | ◯ | ◯ | 2 nm | 4 nm | No |
| 6 | ◯ | ◯ | ◯ | ◯ | 3 nm | 7 nm | No |
| 7 | ◯ | ◯ | | ◯ | 3 nm | 6 nm | No |
| Comparative | | | | | | | |
| Examples | | | | | | | |
| 1 | — | — | — | — | 8 nm | 14 nm | Yes |
| 2 | ◯ | — | — | — | 10 nm | 17 nm | Yes |
| 3 | ◯ | — | ◯ | ◯ | 5 nm | 9 nm | Yes |
| 4 | ◯ | ◯ | — | ◯ | 8 nm | 15 nm | Yes |

In Table 1, “stage 1 polishing” in the manufacturing conditions for the glass substrate 1 means polishing of a surface of the glass substrate 1 using a cerium oxide powder having a mean particle diameter of approximately 1 μm, “mixed liquid washing ” means washing of the surface of the glass substrate 1 using a mixed liquid of sulfuric acid and ascorbic acid, “etching” means etching of the surface of the glass substrate 1 using a hydrofluoric acid aqueous solution, and “alkaline washing” means washing of the surface of the glass substrate 1 using a predetermined alkaline liquid carried out after the mixed liquid washing and/or etching of the surface of the glass substrate 1. Moreover, the light emission characteristics of the organic EL devices 10 were evaluated as the presence/absence of non-luminescent spots, this being according to whether or not non-luminescent spots were found on the organic EL device 10.

### Example 1

A soda-lime glass substrate 1 having a surface smoothness Rz of 4 nm that had been prepared using a float process was used. The surface smoothness Rz of the ITO film 3 was 7 nm, and non-luminescent spots were not found on the organic EL device 10.

### Example 2

A soda-lime glass substrate 1 having a surface smoothness Rz of 8 nm that had been prepared using a float process was subjected to etching using a hydrofluoric acid aqueous solution, thus controlling the surface smoothness Rz to 3 nm, and then this glass substrate 1 was used. The surface smoothness Rz of the ITO film 3 was 6 nm, and non-luminescent spots were not found on the organic EL device 10.

### Example 3

A soda-lime glass substrate 1 having a surface smoothness Rz of 4 nm that had been prepared using a float process was subjected to etching using a hydrofluoric acid aqueous solution followed by alkaline washing, thus controlling the surface smoothness Rz to 2 nm, and then this glass substrate 1 was used. The surface smoothness Rz of the ITO film 3 was 4 nm, and non-luminescent spots were not found on the organic EL device 10.

### Example 4

A surface of a soda-lime glass substrate 1 that had been prepared using a float process was polished using a cerium oxide powder having a mean particle diameter of approximately 1 μm, the cerium oxide powder was removed by carrying out mixed liquid washing using sulfuric acid and ascorbic acid, and etching was carried out using a hydrofluoric acid aqueous solution, thus controlling the surface smoothness Rz to 4 nm, and then this glass substrate 1 was used. The surface smoothness Rz of the ITO film 3 was 8 nm, and non-luminescent spots were not found on the organic EL device 10.

### Example 5

A surface of a soda-lime glass substrate 1 that had been prepared using a float process was polished using a cerium oxide powder having a mean particle diameter of approximately 1 μm, the cerium oxide powder was removed by carrying out mixed liquid washing using sulfuric acid and ascorbic acid, and etching was carried out using a hydrofluoric acid aqueous solution followed by alkaline washing, thus controlling the surface smoothness Rz to 2 nm, and then this glass substrate 1 was used. The surface smoothness Rz of the ITO film 3 was 4 nm, and non-luminescent spots were not found on the organic EL device 10.

### Example 6

A surface of a soda-lime glass substrate 1 that had been prepared using a float process was polished using a cerium oxide powder having a mean particle diameter of approximately 1 μm, the cerium oxide powder was removed by carrying out mixed liquid washing using sulfuric acid and ascorbic acid, and etching was carried out using a hydrofluoric acid aqueous solution followed by alkaline washing, thus controlling the surface smoothness Rz to 3 nm, and then this glass substrate 1 was used. The surface smoothness Rz of the ITO film 3.was 7 nm, and non-luminescent spots were not found on the organic EL device 10.

### Example 7

A surface of a soda-lime glass substrate 1 that had been prepared using a float process was polished using a cerium oxide powder having a mean particle diameter of approximately 1 μm, the polished glass substrate 1 was immersed in a mixed aqueous solution of sulfuric acid, ascorbic acid and hydrofluoric acid, and then the surface of the glass substrate 1 was subjected to alkaline washing, thus controlling the surface smoothness Rz to 3 nm, and then this glass substrate 1 was used. The surface smoothness Rz of the ITO film 3 was 6 nm, and non-luminescent spots were not found on the organic EL device 10.

### Comparative Example 1

A soda-lime glass substrate 1 having a surface smoothness Rz of 8 nm that had been prepared using a float process was used. The surface smoothness Rz of the ITO film 3 was 14 nm, and non-luminescent spots were found on the organic EL device 10.

### Comparative Example 2

A surface of a soda-lime glass substrate 1 that had been prepared using a float process was polished using a cerium oxide powder having a mean particle diameter of approximately 1 am, thus controlling the surface smoothness Rz to 10 nm, and then this glass substrate 1 was used. The surface smoothness Rz of the ITO film 3 was 17 nm, and non-luminescent spots were found on the organic EL device 10.

### Comparative Example 3

A surface of a soda-lime glass substrate 1 that had been prepared using a float process was polished using a cerium oxide powder having a mean particle diameter of approximately 1 μm, and etching was carried out using a hydrofluoric acid aqueous solution followed by alkaline washing, thus controlling the surface smoothness Rz to 5 nm, and then this glass substrate 1 was used. The surface smoothness Rz of the ITO film 3 was 9 nm, and non-luminescent spots were found on the organic EL device 10.

### Comparative Example 4

A surface of a soda-lime glass substrate 1 that had been prepared using a float process was polished using a cerium oxide powder having a mean particle diameter of approximately 1 μm, the cerium oxide powder was removed by carrying out mixed liquid washing using sulfuric acid and ascorbic acid, and then alkaline washing was carried out, thus controlling the surface smoothness Rz to 8 nm, and then this glass substrate 1 was used. The surface smoothness Rz of the ITO film 3 was 15 nm, and non-luminescent spots were found on the organic EL device 10.

According to Examples 1 to 7 and Comparative Examples 1 to 4 described above, it was found that if a glass substrate 1 having a surface smoothness satisfying 0 nm≦Rz≦4 nm, or a glass substrate 1 for which the surface smoothness has been controlled to satisfy 0 nm≦Rz≦4 nm, is used, then an ITO film-formed substrate 4 for which the surface smoothness of the ITO film 3 satisfies 0 nm≦Rz≦8 nm can be manufactured, and hence non-luminescent spots do not occur on the surface of an organic EL device 10 and thus the durability of the organic EL device 10 can be improved. Furthermore, according to Comparative Examples 1 to 4, it was found that if the surface smoothness of the glass substrate 1 is controlled to satisfy Rz>4 nm, then an ITO film-formed substrate 4 for which the surface smoothness of the ITO film 3 satisfies 0 nm≦Rz≦8 nm cannot be manufactured.

Moreover, according to Examples 1 to 3, it was found that if polishing of the surface of the glass substrate 1 is omitted, then polishing of the surface of the glass substrate 1 becomes unnecessary, and hence costs can be reduced, and moreover the production efficiency can be improved. Furthermore, according to Examples 2 and 3, it was found that if the surface smoothness of the glass substrate 1 is controlled to satisfy 0 nm≦Rz≦4 nm by subjecting the surface of the glass substrate 1 to etching using a hydrofluoric acid aqueous solution as an etchant, then scratches and so on on the glass substrate 1 arising during the polishing step can be removed; it was also found that it is preferable to subject the surface of the glass substrate 1 to alkaline washing after the etching, whereby the surface of the glass substrate 1, which has become rough due to the etchant, can be restored, and hence the transparency of the glass substrate 1 can be increased.

According to Examples 4 to 6, it was found that even in the case that the surface of the glass substrate 1 is polished using a cerium oxide powder having a mean particle diameter of approximately 1 μm, if the surface of the glass substrate 1 is subjected to mixed liquid washing using sulfuric acid and ascorbic acid, then the cerium oxide powder polishing agent and so on can be removed, and if the surface of the glass substrate 1 is subsequently subjected to etching using a hydrofluoric acid aqueous solution as an etchant to control the surface smoothness of the glass substrate 1 to satisfy 0 nm≦Rz≦4 nm, then scratches and so on on the glass substrate 1 arising during the polishing step can be removed; it was also found that it is preferable to subject the surface of the glass substrate 1 to alkaline washing after the etching, whereby the surface of the glass substrate 1, which has become rough due to the etchant, can be restored, and hence the transparency of the glass substrate 1 can be increased.

According to Example 7, it was found that in the case that the surface of the glass substrate 1 is polished using a cerium oxide powder having a mean particle diameter of approximately 1 μm, if the glass substrate 1 is immersed in a mixed aqueous solution of sulfuric acid, ascorbic acid and hydrofluoric acid, and then the surface of the glass substrate 1 is subjected to alkaline washing, then the removal of the polishing agent and the etching can be carried out simultaneously, and effects on a par with those according to Examples 4 to 6 can be provided.

In the first examples described above, a mixed liquid of sulfuric acid and ascorbic acid was used, but it was found that similar results to those of the first examples described above could also be obtained if a mixed liquid of nitric acid and ascorbic acid was used.

A description will now be given of second examples of the present invention.

The present inventors prepared ITO film-formed substrates 4 using glass substrates 1 having different surface smoothnesses Rz and manufacturing conditions, and moreover prepared organic EL devices 10 from the ITO film-formed substrates 4 (Examples 8 to 16, Comparative Examples 5 to 7).

Specifically, glass substrates 1 having different manufacturing conditions were each washed with a dipping-type ultrasonic washing machine using an alkaline detergent, and then dried in a warm air current. Next, each glass substrate 1 was put into an in-line-type vacuum deposition apparatus, heating to approximately 220° C. and exhaustion were carried out, and then Ar gas was introduced, the pressure was adjusted to 0.4 to 0.7 Pa, and an SiO₂ film 2 for alkaline passivation was formed using radio-frequency magnetron sputtering. Without exposing the glass substrate 1 having the SiO₂ film 2 formed thereon to the atmosphere, an ITO film 3 was then formed using an ion plating apparatus as shown in FIG. 2. As a result, an ITO film-formed substrate 4 was prepared from each glass substrate 1.

Next, each ITO film-formed substrate 4 was put into a vacuum deposition apparatus, evacuation was carried out down to a pressure of not more than 1.3×10⁻⁴ Pa, and then triphenyl diamine (TPD) as a hole transport layer 5 and an aluminum quinolinol complex (Alq3) as a light-emitting layer 6 were formed. Next, an MgAg alloy film (Mg:Ag=10:1), which is a thin metallic film layer 7, was formed on the organic layers as a cathode. Without exposing the ITO film-formed substrate 4 on which the above films had been formed to the atmosphere, nitrogen gas was introduced into a vacuum chamber and the ITO film-possessing substrate 4 was fixed to a glass substrate and sealing between them were carried out using an epoxy resin. As a result, an organic EL device 10 was prepared from each ITO film-formed substrate 4.

The surface smoothnesses Rz of the glass substrates 1 having different surface smoothnesses Rz and manufacturing conditions, and of the ITO films 3 of the prepared ITO film-formed substrates 4 were measured using an atomic force microscope, and moreover a direct current was applied to each of the prepared organic EL devices 10, and the light emission characteristics thereof were evaluated. The results are shown in Table 2.

TABLE 2

| | Glass Substrate Manufacturing Conditions | | | | | Rz of | Rz of | Non- |
|---|---|---|---|---|---|---|---|---|
| | Stage 1 | Stage 2 | Mixed Liquid | | Alkaline | Glass | ITO | Luminescent |
| | Polishing | Polishing | Washing | Etching | Washing | Substrate | Film | Spots Present? |
| Examples | | | | | | | | |
| 8 | ◯ | ◯ | — | — | — | 4 nm | 8 nm | No |
| 9 | ◯ | ◯ | ◯ | — | — | 3 nm | 6 nm | No |
| 10 | ◯ | ◯ | ◯ | — | ◯ | 2 nm | 5 nm | No |
| 11 | ◯ | ◯ | — | ◯ | — | 3 nm | 7 nm | No |
| 12 | ◯ | ◯ | — | ◯ | ◯ | 2 nm | 5 nm | No |
| 13 | ◯ | ◯ | ◯ | ◯ | — | 2 nm | 6 nm | No |
| 14 | ◯ | ◯ | ◯ | ◯ | ◯ | 2 nm | 4 nm | No |
| 15 | ◯ | ◯ | ◯ | | — | 2 nm | 6 nm | No |
| 16 | ◯ | ◯ | ◯ | | ◯ | 2 nm | 5 nm | No |
| Comparative | | | | | | | | |
| Examples | | | | | | | | |
| 5 | — | — | — | — | — | 6 nm | 10 nm | Yes |
| 6 | ◯ | — | — | — | — | 10 nm | 19 nm | Yes |
| 7 | ◯ | — | — | ◯ | ◯ | 7 nm | 12 nm | Yes |

In Table 2, “stage 1 polishing” in the manufacturing conditions for the glass substrate 1 means polishing of a surface of the glass substrate 1 using a cerium oxide powder having a mean particle diameter of approximately 1 μm, “stage 2 polishing” means subjecting the surface of the glass substrate 1 to finishing polishing using a cerium oxide powder having a mean particle diameter of approximately 0.6 μm after the polishing using a cerium oxide powder having a mean particle diameter of approximately 1 μm, “mixed liquid washing” means washing of the surface of the glass substrate 1 using a mixed liquid of nitric acid and ascorbic acid, “etching” means etching of the surface of the glass substrate 1 using a hydrofluoric acid aqueous solution, and “alkaline washing” means washing of the surface of the glass substrate 1 using a predetermined alkaline liquid carried out after the mixed liquid washing and/or etching. Moreover, the light emission characteristics of the organic EL devices 10 were evaluated as the presence/absence of non-luminescent spots, this being according to whether or not non-luminescent spots were found on the organic EL device 10.

### Example 8

A surface of a soda-lime glass substrate 1 that had been prepared using a float process was subjected to stage 1 polishing using a cerium oxide powder having a mean particle diameter of approximately 1 μm, and then to finishing polishing (stage 2 polishing) using a cerium oxide powder having a mean particle diameter of approximately 0.6 μm, thus controlling the surface smoothness Rz to 4 nm, and then this glass substrate 1 was used. The surface smoothness Rz of the ITO film 3 was 8 nm, and non-luminescent spots were not found on the organic EL device 10.

### Example 9

A surface of a soda-lime glass substrate 1 that had been prepared using a float process was subjected to stage 1 polishing using a cerium oxide powder having a mean particle diameter of approximately 1 μm, then to finishing polishing using a cerium oxide powder having a mean particle diameter of approximately 0.6 μm, and then the cerium oxide powder was removed by carrying out mixed liquid washing using nitric acid and ascorbic acid, whereby the surface smoothness Rz was controlled to 3 nm, and then this glass substrate 1 was used. The surface smoothness Rz of the ITO film 3 was 6 nm, and non-luminescent spots were not found on the organic EL device 10.

### Example 10

A surface of a soda-lime glass substrate 1 that had been prepared using a float process was subjected to stage 1 polishing using a cerium oxide powder having a mean particle diameter of approximately 1 μm, then to finishing polishing using a cerium oxide powder having a mean particle diameter of approximately 0.6 μm, and then the cerium oxide powder was removed by carrying out mixed liquid washing using nitric acid and ascorbic acid, and alkaline washing was carried out, whereby the surface smoothness Rz was controlled to 2 nm, and then this glass substrate 1 was used. The surface smoothness Rz of the ITO film 3 was 5 nm, and non-luminescent spots were not found on the organic EL device 10.

### Example 11

A surface of a soda-lime glass substrate 1 that had been prepared using a float process was subjected to stage 1 polishing using a cerium oxide powder having a mean particle diameter of approximately 1 μm, then to finishing polishing using a cerium oxide powder having a mean particle diameter of approximately 0.6 μm, and then etching was carried out using a hydrofluoric acid aqueous solution, whereby the surface smoothness Rz was controlled to 3 nm, and then this glass substrate 1 was used. The surface smoothness Rz of the ITO film 3 was 7 nm, and non-luminescent spots were not found on the organic EL device 10.

### Example 12

A surface of a soda-lime glass substrate 1 that had been prepared using a float process was subjected to stage 1 polishing using a cerium oxide powder having a mean particle diameter of approximately 1 μm, then to finishing polishing using a cerium oxide powder having a mean particle diameter of approximately 0.6 μm, and then etching was carried out using a hydrofluoric acid aqueous solution followed by alkaline washing, whereby the surface smoothness Rz was controlled to 2 nm, and then this glass substrate 1 was used. The surface smoothness Rz of the ITO film 3 was 5 nm, and non-luminescent spots were not found on the organic EL device 10.

### Example 13

A surface of a soda-lime glass substrate 1 that had been prepared using a float process was subjected to stage 1 polishing using a cerium oxide powder having a mean particle diameter of approximately 1 μm, then to finishing polishing using a cerium oxide powder having a mean particle diameter of approximately 0.6 μm, then the cerium oxide powder was removed by carrying out mixed liquid washing using nitric acid and ascorbic acid, and then etching was carried out using a hydrofluoric acid aqueous solution, whereby the surface smoothness Rz was controlled to 2 nm, and then this glass substrate 1 was used. The surface smoothness Rz of the ITO film 3 was 6 nm, and non-luminescent spots were not found on the organic EL device 10.

### Example 14

A surface of a soda-lime glass substrate 1 that had been prepared using a float process was subjected to stage 1 polishing using a cerium oxide powder having a mean particle diameter of approximately 1 μm, then to finishing polishing using a cerium oxide powder having a mean particle diameter of approximately 0.6 μm, then the cerium oxide powder was removed by carrying out mixed liquid washing using nitric acid and ascorbic acid, and then etching was carried out using a hydrofluoric acid aqueous solution followed by alkaline washing, whereby the surface smoothness Rz was controlled to 2 nm, and then this glass substrate 1 was used. The surface smoothness Rz of the ITO film 3 was 4 nm, and non-luminescent spots were not found on the organic EL device 10.

### Example 15

A surface of a soda-lime glass substrate 1 that had been prepared using a float process was subjected to stage 1 polishing using a cerium oxide powder having a mean particle diameter of approximately 1 μm, then to finishing polishing using a cerium oxide powder having a mean particle diameter of approximately 0.6 μm, and then the polished glass substrate 1 was immersed in a mixed aqueous solution of nitric acid, sulfuric acid, ascorbic acid and hydrofluoric acid, whereby the surface smoothness Rz was controlled to 2 nm, and then this glass substrate 1 was used. The surface smoothness Rz of the ITO film 3 was 6 nm, and non-luminescent spots were not found on the organic EL device 10.

### Example 16

A surface of a soda-lime glass substrate 1 that had been prepared using a float process was subjected to stage 1 polishing using a cerium oxide powder having a mean particle diameter of approximately 1 μm, then to finishing polishing using a cerium oxide powder having a mean particle diameter of approximately 0.6 μm, then the polished glass substrate 1 was immersed in a mixed aqueous solution of nitric acid, sulfuric acid, ascorbic acid and hydrofluoric acid, and then the surface of the glass substrate 1 was subjected to alkaline washing, whereby the surface smoothness Rz was controlled to 2 nm, and then this glass substrate 1 was used. The surface smoothness Rz of the ITO film 3 was 5 nm, and non-luminescent spots were not found on the organic EL device 10.

### Comparative Example 5

A soda-lime glass substrate 1 having a surface smoothness Rz of 6 nm that had been prepared using a float process was used. The surface smoothness Rz of the ITO film 3 was 10 nm, and non-luminescent spots were found on the organic EL device 10.

### Comparative Example 6

A surface of a soda-lime glass substrate 1 that had been prepared using a float process was polished using a cerium oxide powder having a mean particle diameter of approximately 1 μm, whereby the surface smoothness Rz was controlled to 10 nm, and then this glass substrate 1 was used. The surface smoothness Rz of the ITO film 3 was 19 nm, and non-luminescent spots were found on the organic EL device 10.

### Comparative Example 7

A surface of a soda-lime glass substrate 1 that had been prepared using a float process was polished using a cerium oxide powder having a mean particle diameter of approximately 1 μm, and then etching was carried out using a hydrofluoric acid aqueous solution followed by alkaline washing, whereby the surface smoothness Rz was controlled to 7 nm, and then this glass substrate 1 was used. The surface smoothness Rz of the ITO film 3 was 12 nm, and non-luminescent spots were found on the organic EL device 10.

According to Examples 8 to 16 and Comparative Examples 5 to 7, it was found that if a glass substrate 1 that has had the surface smoothness thereof controlled to satisfy 0 nm≦Rz≦4 nm by subjecting the surface thereof to 2-stage polishing is used, then an ITO film-formed substrate 4 for which the surface smoothness of the ITO film 3 satisfies 0 nm≦Rz≦8 nm can be manufactured, and hence non-luminescent spots do not occur on the surface of an organic EL device 10 and thus the durability of the organic EL device 10 can be improved. Furthermore, according to Comparative Examples 5 to 7, it was found that if a glass substrate 1 that has had the surface smoothness thereof controlled to satisfy Rz>4 nm is used, then an ITO film-formed substrate 4 for which the surface smoothness of the ITO film 3 satisfies 0 nm≦Rz≦8 nm cannot be manufactured.

Moreover, according to Examples 8 to 14, it was found that if the surface of the glass substrate 1 is subjected to stage 1 polishing using a cerium oxide powder having a mean particle diameter of approximately 1 μm, and then to finishing polishing (stage 2 polishing) using a cerium oxide powder having a mean particle diameter of approximately 0.6 μm, then the surface smoothness of the glass substrate 1 can be controlled to satisfy 0 nm≦Rz≦4 nm reliably.

Moreover, it was found that it is preferable to subject the surface of the glass substrate 1 to mixed liquid washing using nitric acid and ascorbic acid after the 2-stage polishing has been carried out, whereby the cerium oxide powder polishing agent and so on can be removed, and it was also found that, after the 2-stage polishing has been carried out, it is preferable to subject the surface of the glass substrate 1 to etching using a hydrofluoric acid aqueous solution as an etchant to control the surface smoothness of the glass substrate 1 to satisfy 0 nm≦Rz≦4 nm, whereby scratches and so on on the glass substrate 1 arising during the polishing step can be removed. Furthermore, it was found that it is more preferable to subject the surface of the glass substrate 1 to mixed liquid washing as described above and then etching as described above after the 2-stage polishing has been carried out. Yet more preferably, the surface of the glass substrate 1 is subjected to alkaline washing after the mixed liquid washing and/or etching, whereby the surface of the glass substrate 1, which has become rough due to the mixed liquid and/or etchant, can be restored, and hence the transparency of the glass substrate 1 can be increased.

According to Examples 15 and 16, it was found that if, after the 2-stage polishing has been carried out, the glass substrate 1 is immersed in a mixed aqueous solution of nitric acid, sulfuric acid, ascorbic acid and hydrofluoric acid, and then preferably the surface of the glass substrate 1 is subjected to alkaline washing, then the removal of the polishing agent and the etching can be carried out simultaneously, and effects on a par with those according to Examples 13 and 14 can be provided.

In the examples 9, 10,13 and 14 described above, a mixed liquid of nitric acid and ascorbic acid was used, but it was found that similar results to those of the examples 9, 10, 13 and 14 described above could also be obtained if a mixed liquid of sulfuric acid and ascorbic acid was used.

In the examples described above, the etchant used was made to be an acidic aqueous solution containing a strong acid such as hydrofluoric acid, but it was found that results similar to those of the examples described above could also be obtained if an alkaline aqueous solution containing a strong alkali such as potassium hydroxide or sodium hydroxide was used.

Moreover, in the examples described above, the ITO film 3 was formed on the glass substrate 1 using ion plating; however, there is no limitation thereto, but rather it was found that results similar to those of the examples described above could also be obtained if the ITO film 3 was formed using sputtering, electron beam (EB) deposition or the like.

Moreover, in the examples 15, 16 described above, a mixed aqueous solution of nitric acid, sulfuric acid, ascorbic acid and hydrofluoric acid was used, but it was found that results similar to those of the examples 15, 16 described above could also be obtained if a mixed aqueous solution of sulfuric acid, ascorbic acid and hydrofluoric acid, or a mixed aqueous solution of nitric acid, sulfuric acid, ascorbic acid and hydrofluoric acid was used.

### Industrial Applicability

As described in detail above, according to the first and third aspects of the present invention, there are provided a method of manufacturing a transparent substrate according to which the surface smoothness of a surface of a transparent substrate that is to have a transparent conductive film formed on the surface thereof is controlled to satisfy 0 nm≦Rz≦4 nm, and such a transparent substrate; as a result, non-luminescent spots do not occur and hence durability can be improved.

Moreover, in the first and third aspects, polishing of the surface of the transparent substrate is omitted; as a result, polishing of the surface of the transparent substrate becomes unnecessary, and hence costs can be reduced, and moreover the transparent substrate production efficiency can be improved.

In the first and third aspects, the surface of the transparent substrate is subjected to etching using an acidic aqueous solution containing hydrofluoric acid or an alkaline aqueous solution containing potassium hydroxide or sodium hydroxide; as a result, the step of polishing the surface of the transparent substrate can be eliminated reliably.

In the first and third aspects, after the etching has been carried out, the surface of the transparent substrate is subjected to alkaline washing comprising washing using an alkaline liquid; as a result, the transparency of the surface of the transparent substrate, which has become rough due to the etchant, can be increased.

In the first and third aspects, the surface of the transparent substrate is polished; as a result, the surface smoothness of the surface of the transparent substrate can be controlled reliably.

In the first and third aspects, the surface of the transparent substrate is polished using a cerium oxide powder having a predetermined mean particle diameter, then the surface of the transparent substrate is washed using a mixed liquid of sulfuric acid and ascorbic acid or a mixed liquid of nitric acid and ascorbic acid, and then the surface of the transparent substrate is subjected to etching using an acidic aqueous solution containing hydrofluoric acid or an alkaline aqueous solution containing potassium hydroxide or sodium hydroxide; as a result, the surface smoothness of the surface of the transparent substrate can be controlled more reliably.

In the first and third aspects, the surface of the transparent substrate is polished using a cerium oxide powder having a predetermined mean particle diameter, and then using a cerium oxide powder having a mean particle diameter lower than the predetermined mean particle diameter; as a result, the surface smoothness of the surface of the transparent substrate can be controlled more reliably.

In the first and third aspects, after the polishing of the surface of the transparent substrate has been carried out, the surface of the transparent substrate is washed using a mixed liquid of sulfuric acid and ascorbic acid or a mixed liquid of nitric acid and ascorbic acid; as a result, polishing agent and so on on the transparent substrate can be removed effectively.

In the first and third aspects, after the surface of the transparent substrate has been washed, the surface of the transparent substrate is subjected to alkaline washing comprising washing using an alkaline liquid; as a result, the transparency of the surface of the transparent substrate, which has become rough due to the mixed liquid of sulfuric acid and ascorbic acid or the mixed liquid of nitric acid and ascorbic acid, can be increased.

In the first and third aspects, after the surface of the transparent substrate has been washed, the surface of the transparent substrate is subjected to etching using an acidic aqueous solution containing hydrofluoric acid or an alkaline aqueous solution containing potassium hydroxide or sodium hydroxide; as a result, scratches and so on on the transparent substrate from which the polishing agent and so on has been removed can be removed effectively.

In the first and third aspects, after the polishing of the surface of the transparent substrate has been carried out, the surface of the transparent substrate is subjected to etching using an acidic aqueous solution containing hydrofluoric acid or an alkaline aqueous solution containing potassium hydroxide or sodium hydroxide; as a result, scratches and so on on the polished transparent substrate can be removed effectively.

As described in detail above, according to the second aspect of the present invention, there is provided a transparent substrate manufactured using a method of manufacturing a transparent substrate according to the first aspect of the present invention; as a result, the transparent substrate can be used in an organic EL device having high durability with no non-luminescent spots.

In the second and third aspects, there is provided a transparent substrate having a transparent conductive film formed on a surface thereof, wherein the surface smoothness of the surface of the transparent conductive film satisfies 0 nm≦Rz≦8 nm; as a result the transparent substrate can be used in an organic EL device having high durability with no non-luminescent spots.

As described in detail above, according to the fourth aspect of the present invention, there is provided an electroluminescent device having a transparent substrate according to the second or third aspect of the present invention; as a result, an organic EL device having high durability with no non-luminescent spots can be provided.

1. A method of manufacturing a transparent substrate that is to have a transparent conductive film formed on a surface thereof, characterized by controlling a surface smoothness of the surface of the transparent substrate to satisfy 0 nm≦Rz≦4 nm.

2. A method of manufacturing a transparent substrate as claimed in claim 1, characterized in that the controlling of the surface smoothness is carried out by omitting polishing of the surface of the transparent substrate.

3. A method of manufacturing a transparent substrate as claimed in claim 2, characterized in that the surface of the transparent substrate is subjected to etching using an acidic aqueous solution containing hydrofluoric acid or an alkaline aqueous solution containing potassium hydroxide or sodium hydroxide.

4. A method of manufacturing a transparent substrate as claimed in claim 3, characterized in that after the etching has been carried out, the surface of the transparent substrate is subjected to alkaline washing comprising washing using an alkaline liquid.

5. A method of manufacturing a transparent substrate as claimed in claim 1, characterized in that the controlling of the surface smoothness is carried out mainly by polishing the surface of the transparent substrate.

6. A method of manufacturing a transparent substrate as claimed in claim 5, characterized in that the polishing of the surface of the transparent substrate is carried out using a cerium oxide powder having a predetermined mean particle diameter, and after the polishing of the surface of the transparent substrate has been carried out, the surface of the transparent substrate is washed using a mixed liquid of sulfuric acid and ascorbic acid or a mixed liquid of nitric acid and ascorbic acid, and after the surface of the transparent substrate has been washed, the surface of the transparent substrate is subjected to etching using an acidic aqueous solution containing hydrofluoric acid or an alkaline aqueous solution containing potassium hydroxide or sodium hydroxide.

7. A method of manufacturing a transparent substrate as claimed in claim 6, characterized in that after the etching has been carried out, the surface of the transparent substrate is subjected to alkaline washing comprising washing using an alkaline liquid.

8. A method of manufacturing a transparent substrate as claimed in claim 5, characterized in that polishing of the surface of the transparent substrate is carried out using a cerium oxide powder having a predetermined mean particle diameter, and is then further carried out using a cerium oxide powder having a mean particle diameter lower than the predetermined mean particle diameter.

9. A method of manufacturing a transparent substrate as claimed in claim 8, characterized in that after the polishing of the surface of the transparent substrate has been carried out, the surface of the transparent substrate is washed using a mixed liquid of sulfuric acid and ascorbic acid or a mixed liquid of nitric acid and ascorbic acid.

10. A method of manufacturing a transparent substrate as claimed in claim 9, characterized in that after the surface of the transparent substrate has been washed, the surface of the transparent substrate is subjected to alkaline washing comprising washing using an alkaline liquid.

11. A method of manufacturing a transparent substrate as claimed in claim 9, characterized in that after the surface of the transparent substrate has been washed, the surface of the transparent substrate is subjected to etching using an acidic aqueous solution containing hydrofluoric acid or an alkaline aqueous solution containing potassium hydroxide or sodium hydroxide.

12. A method of manufacturing a transparent substrate as claimed in claim 8, characterized in that after the polishing of the surface of the transparent substrate has been carried out, the surface of the transparent substrate is subjected to etching using an acidic aqueous solution containing hydrofluoric acid or an alkaline aqueous solution containing potassium hydroxide or sodium hydroxide.

13. A method of manufacturing a transparent substrate as claimed in claim 11, characterized in that after the etching has been carried out, the surface of the transparent substrate is subjected to alkaline washing comprising washing using an alkaline liquid.

14. A transparent substrate, characterized by having been manufactured using a method of manufacturing a transparent substrate as claimed in claim 1.

15. A transparent substrate as claimed in claim 14, characterized in that a transparent conductive film is formed on the surface thereof, and a surface smoothness of a surface of the transparent conductive film satisfies 0 nm≦Rz≦8 nm.

16. A transparent substrate that is to have a transparent conductive film formed on a surface thereof, characterized in that a surface smoothness of said surface thereof satisfies 0 nm≦Rz≦4 nm.

17. A transparent substrate as claimed in claim 16, characterized in that polishing of said surface has been omitted.

18. A transparent substrate as claimed in claim 17, characterized in that said surface has been subjected to etching using an acidic aqueous solution containing hydrofluoric acid or an alkaline aqueous solution containing potassium hydroxide or sodium hydroxide.

19. A transparent substrate as claimed in claim 18, characterized in that after the etching has been carried out, said surface has been subjected to alkaline washing comprising washing using an alkaline liquid.

20. A transparent substrate as claimed in claim 16, characterized in that said surface has been polished.

21. A transparent substrate as claimed in claim 20, characterized in that the polishing of said surface has been carried out using a cerium oxide powder having a predetermined mean particle diameter, and after the polishing of said surface has been carried out, said surface has been washed using a mixed liquid of sulfuric acid and ascorbic acid or a mixed liquid of nitric acid and ascorbic acid, and after said surface has been washed, said surface has been subjected to etching using an acidic aqueous solution containing hydrofluoric acid or an alkaline aqueous solution containing potassium hydroxide or sodium hydroxide.

22. A transparent substrate as claimed in claim 21, characterized in that after the etching has been carried out, said surface has been subjected to alkaline washing comprising washing using an alkaline liquid.

23. A transparent substrate as claimed in claim 20, characterized in that polishing of said surface has been carried out using a cerium oxide powder having a predetermined mean particle diameter, and has then further been carried out using a cerium oxide powder having a mean particle diameter lower than the predetermined mean particle diameter.

24. A transparent substrate as claimed in claim 23, characterized in that after the polishing of said surface has been carried out, said surface has been washed using a mixed liquid of sulfuric acid and ascorbic acid or a mixed liquid nitric acid and ascorbic acid.

25. A transparent substrate as claimed in claim 24, characterized in that after said surface has been washed, said surface has been subjected to alkaline washing comprising washing using an alkaline liquid.

26. A transparent substrate as claimed in claim 24, characterized in that after said surface has been washed, said surface has been subjected to etching using an acidic aqueous solution containing hydrofluoric acid or an alkaline aqueous solution containing potassium hydroxide or sodium hydroxide.

27. A transparent substrate as claimed in claim 23, characterized in that after the polishing of said surface has been carried out, said surface has been subjected to etching using an acidic aqueous solution containing hydrofluoric acid or an alkaline aqueous solution containing potassium hydroxide or sodium hydroxide.

28. A transparent substrate as claimed in claim 26, characterized in that after the etching has been carried out, said surface has been subjected to alkaline washing comprising washing using an alkaline liquid.

29. A transparent substrate as claimed in claim 16, characterized in that a transparent conductive film is formed on said surface thereof, and a surface smoothness of a surface of said transparent conductive film satisfies 0 nm≦Rz≦8 nm.

30. An electroluminescent device characterized by having a transparent substrate as claimed in claim 16.
